(19) United States
(12) Patent Application Publication
(10) Pub. No.: US 2013/0173972 A1
(43) Pub. Date: Jul. 4, 2013

(54) SYSTEM AND METHOD FOR SOLID STATE DISK FLASH PLANE FAILURE DETECTION

(71) Applicant: Robert Kubo, Escondido, CA (US)

(72) Inventor: Robert Kubo, Escondido, CA (US)

(21) Appl. No.: 13/372,563

(22) Filed: Feb. 14, 2012

Related U.S. Application Data
(60) Provisional application No. 61/580,941, filed on Dec. 28, 2011.

(51) Int. Cl. G11C 29/08; G06F 11/26

(52) U.S. Cl. 714/718; 714/E11.159

(57) ABSTRACT

A system and method for early detection and reporting of an impending NAND Flash device plane failure. Each time that a data unit is retrieved from a NAND Flash array the number of bits in error and the memory location associated with the errors is observed. if the number of bits in error or the error rate for a memory location exceeds a threshold of the number of bits in error per data, retrieval, or number of bits in error per data unit per unit time, a NAND Flash plane failure Patrol Read operation is performed at the memory location, regardless of where in the cycle the Patrol Read function is in a scrub of the overall NAND Flash device. The NAND Flash plane failure Patrol Read is repeated for a number of cycles on the NAND Flash plane in question.

### CROSS REFERENCE TO RELATED APPLICATIONS

This application claims priority under 35 U.S.C. §119(e) to the following co-pending and commonly-assigned provisional patent application, which is incorporated herein by reference:

Provisional Patent Application Ser. No. 61/580,941, entitled “SYSTEM AND METHOD FOR SOLID STATE DISK FLASH PLANE FAILURE DETECTION” by Robert Kubo; filed on Dec. 28, 2011.

### FIELD OF THE INVENTION

The present invention relates to solid state disk (SSD) storage devices, and in particular, to detection of imminent NAND flash plane failures within SSD storage devices.

### BACKGROUND OF THE INVENTION

Solid state storage, in particular, flash-based devices either in. solid state disks (SSDs) or on flash cards, is quickly emerging as a credible tool for use in enterprise storage solutions. Ongoing technology developments have vastly improved performance and provided for advances in enterprise-class solid state reliability and endurance. As a result, solid state storage, specifically flash storage deployed in SSDs, are becoming vital for delivering higher performance to servers and storage systems, such as the data warehouse system illustrated in FIG. 1. The system illustrated, a product of Teradata Corporation, is a hybrid data warehousing platform that provides the capacity and cost benefits of hard disk drives (HDDs) while leveraging the performance advantage of solid-state drives (SSDs). As shown the system includes multiple physical database servers 101, connected together through a communication network 105. Each server has access to SSDs 120, providing fast storage and retrieval of high demand “hot” data, and HDDs 110, providing economical storage of lesser used “cold” data. Teradata Virtual Storage software automatically migrates data to the appropriate device to match its temperature.

SSDs are packaged similarly to HDDs in form factor modules that are typically 3.5 inches or 2.5 inches for enterprise and 1.8 inches for consumer drives. They communicate with an I/O controller, host adapter or storage controller in the same manner as HDDs via a standard I/O interface such as Fibre Channel (FC), Serial Attached SCSI (SAS) or Serial Advanced Technology Attachment (SATA). But access to data in SSD storage and data transfer rates for SSD storage are much faster than for HDD storage, as illustrated in FIG. 2. FIG. 2 provides a comparison of data access times and data transfer rates for conventional HDD storage devices 210, SSD storage devices 220, DRAM memory 230, and CPU cache memory 240.

Most current SSD storage devices use NAND based flash memory which retains memory even without power provided to the memory. However, NAND flash memory is susceptible to failure modes that are uniquely associated with the storage media technology, such as Column and Plane Failures. Due to the speed at which these failures can escalate, it is important to identify potential failures early to ensure the integrity of data at risk due to a NAND flash memory failure.

### BRIEF DESCRIPTION OF THE DRAWINGS

FIG. 1 is an illustration of a multiple-node database system employing SSD storage devices and conventional disk storage devices.

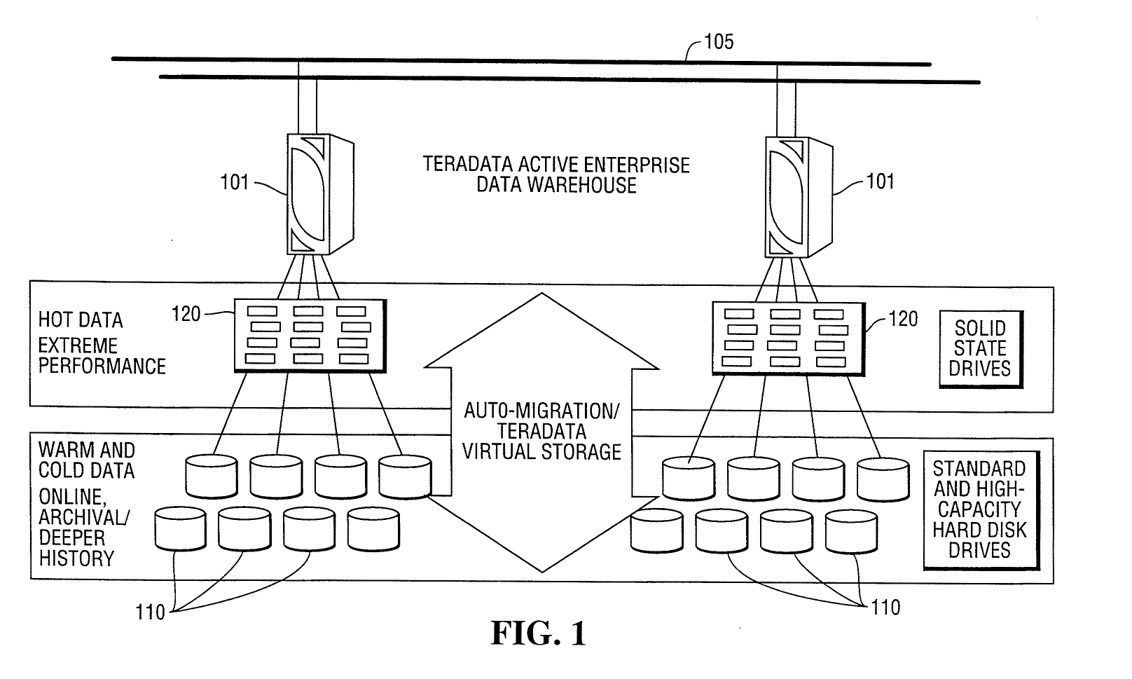

FIG. 2 illustrates the relative differences in data access times for SSD storage devices, conventional disk storage devices, and other components of a computer system.

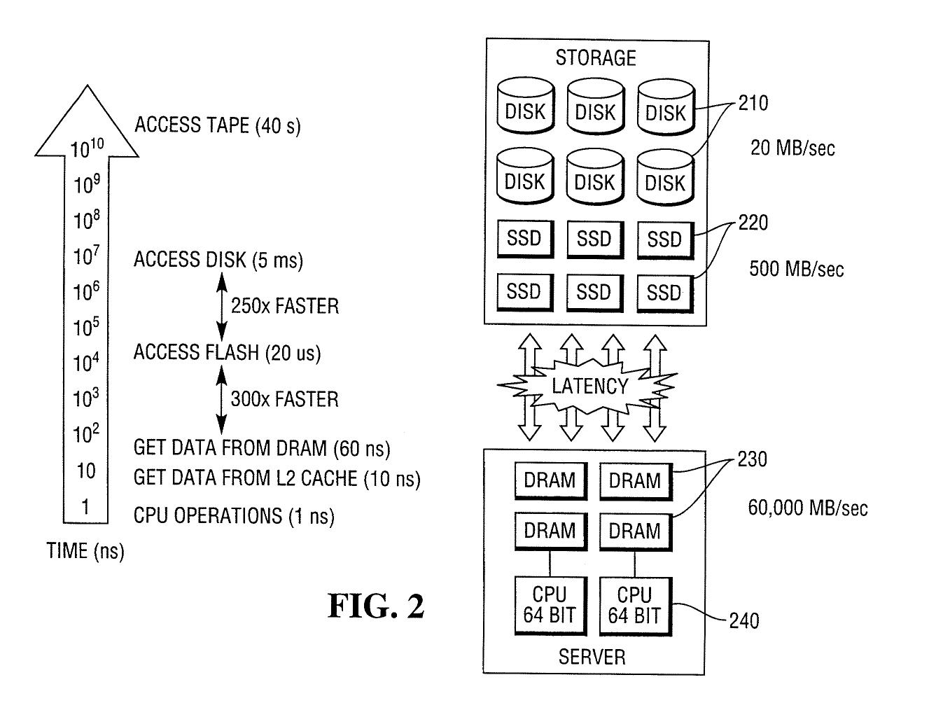

FIG. 3 is a functional diagram of a typical SSD storage device.

FIG. 4 provides an illustration of the internal architecture of a typical NAND flash device.

FIG. 5 provides a flowchart illustrating a method for detection of NAND flash device failures in accordance with the present invention.

### DETAILED DESCRIPTION OF THE INVENTION

NAND Flash memory devices permanently store one or more data bits in a single memory cell, with billions of cells contained in a memory device. SSD technology economically leverages these memory devices along with robust management logic to provide immediate, direct access to the large amounts of non-volatile data stored within these memory devices.

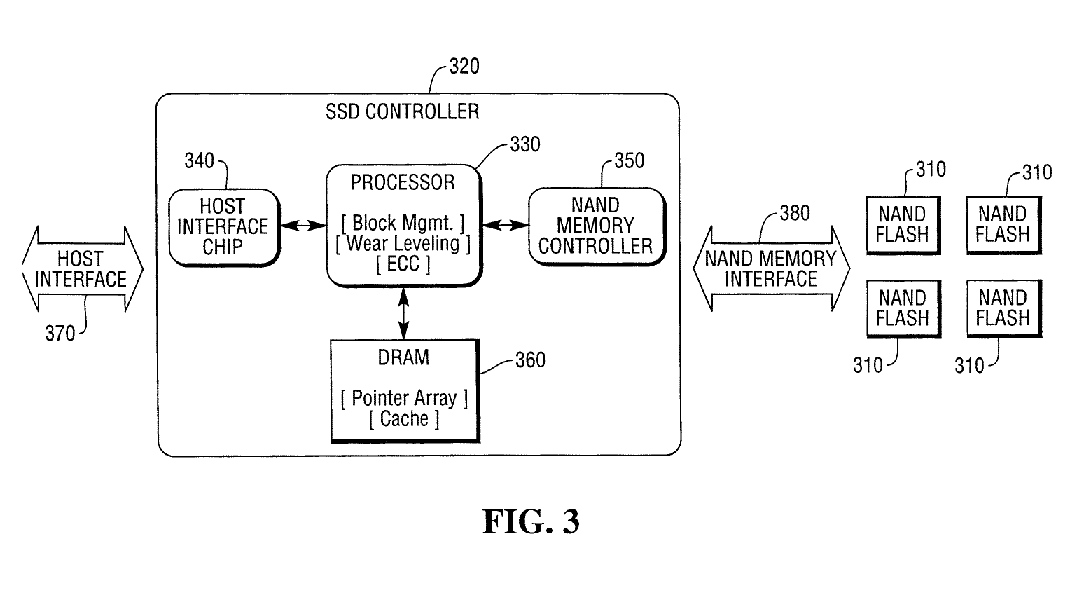

FIG. 3 provides a functional diagram of a typical NAND flash based SSD storage device. The primary components of the SSD are an array of NAND flash memory packages 310 and an SSD controller 320 that contains the operational logic necessary to manage the NAND flash memory 310 and provide a standard storage interface to the host server. SSD controller 320 includes a host interface module 340 to support a physical host interface connection 370, such as Fibre Channel (FC), Serial Attached SCSI (SAS) or Serial Advanced Technology Attachment (SATA). An internal buffer manager holds pending and satisfied requests along the primary data path. A NAND memory controller 350 emits commands and handles transport of data along a memory interface 380 to the NAND flash packages 310. A processor 330 is also required to manage read and write operations to the NAND memory, including error handling and block management. Processor 330, host interface module 340, and NAND memory controller 350 are typically implemented in a discrete component such as an ASIC or FPGA, and data flow between these logic elements is very fast.

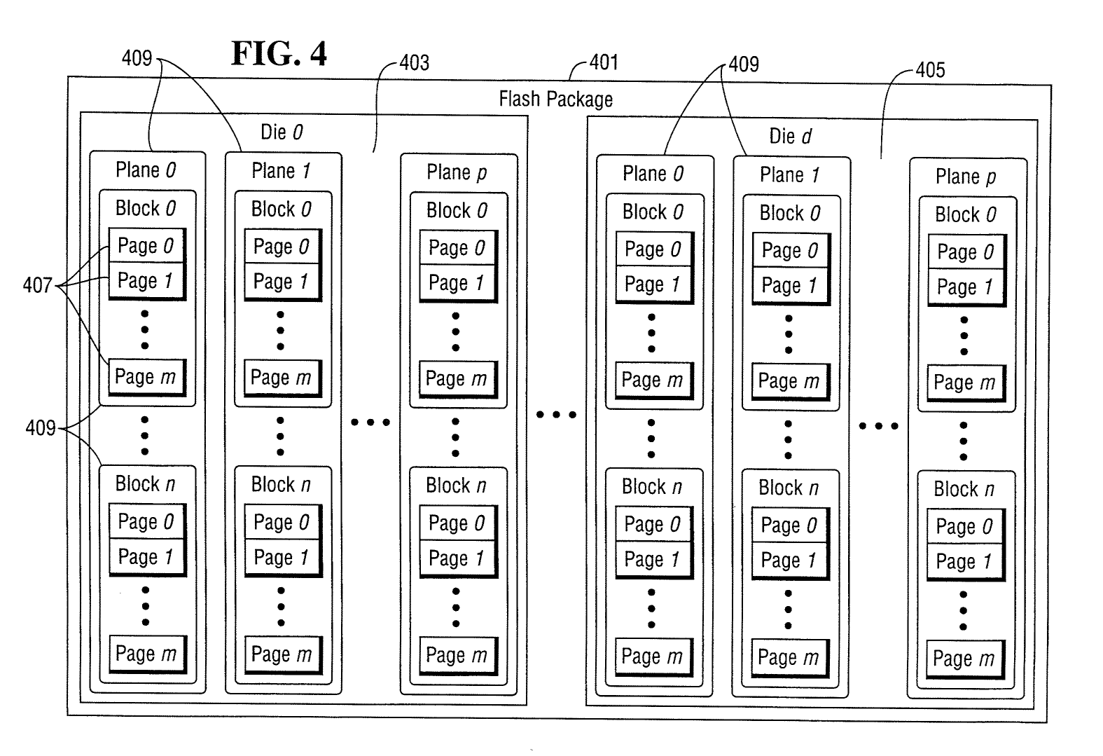

A single NAND flash package comprises billions of flash cells that are organized in a hierarchical architecture, as depicted in FIG. 4. A flash package 401 is composed of one or more dies, two of which, 403 and 405, are shown. The dies may share an I/O bus and a number common control signals, but have separate chip enable and ready/busy signals so that one of the dies can accept commands and data while the other is carrying out another operation. The basic memory unit within the flash package is a flash page 407. Multiple flash pages compose a block 409, which further forms a plane 411. In NAND flash memories, reading and writing are performed in a granularity of flash page. In addition to data, each page includes a region to store metadata, such as identification and error detection information.

As stated above, NAND flash memory is susceptible to column and plane failures. A column failure is defined as a bit location that has a failure in every block on a plane. Error handling and correction features incorporated into the SSD can often correct these errors or move data to other memory locations to prevent data corruption.

A plane failure is similar to a column failure in that it affects all the blocks on a plane. However, a plane failure encompasses all even rows and columns or all odd rows and columns in a NAND die. The difference between a plane failure and a column failure is in two key areas. The first difference is the scope of the errors. Plane failure errors occur in the hundreds and memory function progressively degrades over time. The second difference is that plane failure bit errors are not confined to a fixed bit location. Left unchecked, a plane failure will eventually overwhelm the ECC correction capability of the SSD, with the result that an entire plane appears to fail over a relatively short period of time.

To identify failures and avert unrecoverable data loss, a proactive tool known as Patrol Read is employed. Patrol Read, which is analogous to Background Media Scan in an HDD, is used to verify the flash media by periodically sending internally generated read commands to the media. A background scan of the entire SSD may take days to complete. Once the Patrol Read has checked all the data blocks in the NAND flash media, it repeats the check indefinitely.

The performance and response times of the SSD are not affected by Patrol Read, which executes in a highly parallelized manner and enables many commands to execute simultaneously. Since this is the normal mode of operation, the insertion of a relatively few number of read commands does not impact user commands. The result is that typical workloads response time is unaffected. Under very heavy workloads, priority is given to servicing the I/O workload over the Patrol Read function. Since Patrol Read provides so much extra user data protection with no impact on user performance, it is recommended that Patrol Read never be turned off, but remain enabled to continuously run in the background.

However, a breakdown of a NAND Flash plane remains a serious concern, as the rate of failure may exceed the capability of error detection due to the periodicity of the Patrol Read function validation of the media. Theoretically, in a progressive failure mode, detection and reporting of the NAND Flash plane failure should occur prior to an Unrecoverable READ Error being observed by the user. The normal Patrol Read feature function scans the SSD device storage media logical block addresses (LBAs) in a progressive fashion from lowest to highest to validate that all of the data blocks can be successfully read, and relocated if necessary.

The improved system and method for detecting potential flash memory failures described herein leverages the existing Patrol Read feature function NAND Flash plane failure algorithms, but enhances detection capability by establishing a data unit bit error threshold over unit time, and when the bit error threshold meets or exceeds the threshold triggers a bias of the Patrol Read feature at the NAND Flash plane that contains the data units that met or exceeded the threshold.

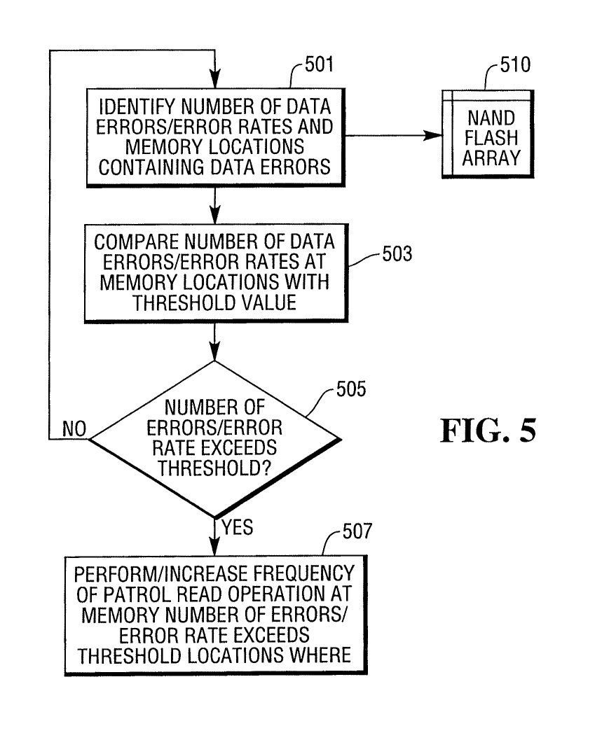

Typically, bad memory units are discovered through normal read and write accesses to the SSD. Each time that a data unit is retrieved from the NAND Flash array the number of bits in error is observed and a determination is made if correction is required, and if the error is correctable. The method of the present, illustrated in the flowchart of FIG. 5, includes a check to determine the historical bits in error for a data storage location (step 501), and if the number of bits in error or the error rate exceeds a threshold of the number of bits in error per data retrieval or number of bits in error per data unit per unit time (steps 503 and 505) it triggers the NAND Flash plane failure Patrol Read (step 507). The NAND Flash plane failure Patrol Read reads the data units associated with the NAND Flash plane that contained the data unit that triggered the invocation of the NAND Flash plane failure Patrol Read regardless of where in the cycle the Patrol Read function is the scrub of the overall SSD device. The NAND Flash plane failure Patrol Read is repeated for a number of cycles (x) on the NAND Flash plane in question.

The system and method provided by this invention enables earlier detection and reporting of an impending NAND Flash device plane failure, which enables a proactive service strategy of device replacement prior to data loss events that may occur as a result.

The foregoing description of the invention has been presented for purposes of illustration and description. It is not intended to be exhaustive or to limit the invention to the precise form disclosed.

Additional alternatives, modifications, and variations will be apparent to those skilled in the art in light of the above teaching. Accordingly, this invention is intended to embrace all alternatives, modifications, equivalents, and variations that fall within the spirit and broad scope of the attached claims.

What is claimed is:

1. A method for verifying solid state memory, comprising the steps of:
identifying, by a processing device, the number of data errors and locations of those errors within a solid state memory device;
comparing, by said processing device, the number of errors at each one of said locations to a threshold value; and
when the number of errors at one of said locations exceeds said threshold value, initiating a patrol read operation at said one of said locations

2. The method according to claim 1, wherein said solid state device is a NAND flash memory device.

3. The method according to claim 2, wherein said NAND flash memory device comprises an SSD.

4. The method according to claim 2, wherein said locations are NAND flash memory pages.

5. The method according to claim 2, wherein said locations are NAND flash memory blocks.

6. The method according to claim 1, wherein said data errors are identified during read and write accesses to said solid state memory device.

7. A method for verifying solid state memory, comprising the steps of:
identifying, by a processing device, the number of data errors and locations of those errors within a NAND flash memory device;
comparing, by said processing device, the number of errors at each one of said locations to a threshold value; and
when the number of errors at one of said locations exceeds said threshold value, increasing the frequency of a patrol read operation at said one of said locations

8. The method according to claim 7, wherein said solid state device is a NAND flash memory device.

9. The method according to claim 8, wherein said NAND flash memory device comprises an SSD.

10. The method according to claim 8, wherein said locations are NAND flash memory pages.

11. The method according to claim 8, wherein said locations are NAND flash memory blocks.

12. The method according to claim 7, wherein said data errors are identified during read and write accesses to said solid state memory device.

13. A method for verifying solid state memory, comprising the steps of:
monitoring, by a processing device, data error rates at a plurality of memory locations within a NAND flash memory device;
comparing, by said processing device, the data error rates at each one of said locations to a threshold value; and
when the data error rate at one of said locations exceeds said threshold value, initiating a patrol read operation at said one of said locations

14. The method according to claim 13, wherein said solid state device is a NAND flash memory device.

15. The method according to claim 14, wherein said NAND flash memory device comprises an SSD.

16. The method according to claim 14, wherein said locations are NAND flash memory pages.

17. The method according to claim 14, wherein said locations are NAND flash memory blocks.

18. The method according to claim 13, wherein said data errors are identified during read and write accesses to said solid state memory device.

19. A method for verifying solid state memory, comprising the steps of:
monitoring, by a processing device, data error rates at a plurality of memory locations within a NAND flash memory device;
comparing, by said processing device, the data error rates at each one of said locations to a threshold value; and
when the data error rate at one of said locations exceeds said threshold value, increasing the frequency of a patrol read operation at said one of said locations

20. The method according to claim 19 wherein said solid state device is a NAND flash memory device.

21. The method according to claim 20, wherein said NAND flash memory device comprises an SSD.

22. The method according to claim 20, wherein said locations are NAND flash memory pages.

23. The method according to claim 20, wherein said locations are NAND flash memory blocks.

24. The method according to claim 19, wherein said data errors are identified during read and write accesses to said solid state memory device.
